(19) United States
(12) Patent Application Publication
(10) Pub. No.: US 2025/0324512 A1
(43) Pub. Date: Oct. 16, 2025

(54) FOLDABLE SENSOR WITH ANISOTROPIC ADHESIVE

(71) Applicant: Tekscan, Inc., Norwood, MA (US)

(72) Inventor: Robert M. Podoloff, Framingham, MA (US)

(73) Assignee: Tekscan, Inc., Norwood, MA (US)

(21) Appl. No.: 19/172,941

(22) Filed: Apr. 8, 2025

Related U.S. Application Data
(60) Provisional application No. 63/632,304, filed on Apr. 10, 2024.

(51) Int. Cl. H05K 1/14; G01L 1/16; H05K 1/03; H05K 1/11

(52) U.S. Cl. CPC H05K 1/147; G01L 1/16; H05K 1/0326; H05K 1/111; H05K 2201/055; H05K 2201/09227; H05K 2201/10151

(57) ABSTRACT

A foldable sensor that can operate without a continuous structural connection is provided. The foldable sensor may be made from a continuous flexible substrate or may be made of two separate pieces of substrate. The foldable sensor is held together with an anisotropic adhesive. The continuous flexible sensor is still operative, via the anisotropic adhesive, if the folded portion severs or if the conductive trace is otherwise disconnected.

### CROSS-REFERENCE TO RELATED APPLICATIONS

This application claims the benefit of priority under 35 U.S.C. § 119(e) of U.S. provisional application Ser. No. 63/632,304, filed Apr. 10, 2024, the disclosures of which is incorporated by reference in its entirety.

### FIELD

The disclosed embodiments generally relate to sensors, for example, piezoelectric force or pressure sensors, where the sensor is foldable and secured with an anisotropic adhesive.

### BACKGROUND

Generally, in the field of sensors, it is faster and more cost effective to manufacture sensor elements as two portions on the same substrate that fold together to make a whole sensor, than it is to layer the sensor elements on top of each other. However, this expedited process of printing circuits may risk the quality of the circuits. If the wires or conductive traces are not properly insulated or improperly positioned, then when the substrate is folded, the sensor may short circuit. Furthermore, the process of folding the sensor may stress the wires or conductive traces and cause them to break. A protective layer may be used to mitigate these issues, but it adds bulk to the sensor. Accordingly, current foldable sensors prompt a compromise between flexibility and reliability.

### SUMMARY

According to one aspect, a foldable sensor that transitions between an a first unfolded state and a second folded state is provided. The foldable sensor includes a substrate. Disposed on the substrate is a conductive trace, and disposed on the conductive trace is a sensor material. The sensor additionally includes an anisotropic adhesive disposed on a portion of the conductive trace.

According to another aspect, a sensor that includes a first substrate with a first substrate top and a second substrate detached from the first substrate with a second substrate top is provided. The top of the second substrate is configured to be mated to the first substrate top when the sensor is functionally aligned. The top of the second substrate further includes an overhang, that is at least in part defined by a portion of the second substrate that is spaced from, or not covered by, the first substrate. The sensor additionally contains a conductive trace, which includes a conductive trace disposed on the first substrate top and the second substrate top. A sensor material is disposed on at least a portion of the conductive trace and positioned between the first substrate and the second substrate when the sensor is functionally aligned. The sensor further includes an interface on the overhang, wherein the conductive trace terminates at the interface.

According to another aspect, a sensor is provided. The sensor includes a first and a second substrate, each with a top and bottom. A conductive trace is disposed on the top of the first substrate and the second substrate. The first conductive trace is disposed on the first substrate and the second substrate, and includes a first plate portion and a first conductive lead. The first plate portion is disposed on first substrate while the first conductive lead terminates on the second substrate. The conductive trace additionally includes a second conductive trace, which originates on the second substrate and terminates on the second substrate. The second conductive trace includes a second plate portion on and a second conductive lead. The first conductive lead and the second conductive lead mutually terminate at an interface on the second substrate. The sensor also includes a sensor material that is disposed on at least one of the first plate portion and the second plate portion. Additionally, the sensor includes an anisotropic adhesive that covers at least a portion of the second substrate and the interface. When the sensor is in a functionally aligned state, the top of the first substrate and the top of the second substrate are mated. In this functionally aligned state, the first plate portion and the second plate portion are configured to functionally align. When the sensor is in the functionally aligned state, the first conductive lead on the first substrate and the first conductive lead on the second substrate are configured are functionally aligned. The sensor includes an overhang where the second substrate is not covered by the first substrate, this overhang contains the interface.

It should be appreciated that the foregoing concepts, and additional concepts discussed below, may be arranged in any suitable combination, as the present disclosure is not limited in this respect. Further, other advantages and novel features of the present disclosure will become apparent from the following detailed description of various non-limiting embodiments when considered in conjunction with the accompanying figures.

### BRIEF DESCRIPTION OF DRAWINGS

The accompanying drawings are not intended to be drawn to scale. In the drawings, each identical or nearly identical component that is illustrated in various figures may be represented by a like numeral. For purposes of clarity, not every component may be labeled in every drawing. In the drawings:

FIG. 1a depicts a flexible substrate with a printable conductive trace;

FIG. 1b depicts the flexible substrate of FIG. 1a with a sensor material;

FIG. 1c depicts a foldable sensor in a first unfolded state;

FIG. 1d depicts the foldable sensor in FIG. 1c in a second folded state;

FIG. 2a illustrates a cropped cross section of the foldable sensor in FIG. 1d across a midline taken along line 2a-2a;

FIG. 2b illustrates a cropped cross section of the foldable sensor in FIG. 1d offset from the midline taken along line 2b-2b;

FIG. 3a depicts the foldable sensor and a printed circuit board;

FIG. 3b depicts the printed circuit board of FIG. 3a where the foldable sensor is aligned with the exposed pads;

FIG. 3c depicts the printed circuit board of FIG. 3b where the foldable sensor is attached to the exposed pads;

FIG. 4a depicts an alternative embodiment of the sensor;

FIG. 4b depicts the alternative embodiment of FIG. 4a in a second folded state;

FIG. 4c depicts an alternative embodiment of the sensor; and

FIG. 4d depicts the alternative embodiment of FIG. 4c in a folded state.

### DETAILED DESCRIPTION

Manufacturing of printable sensors in a foldable format may be preferable because it can be more cost effective and time efficient than traditional methods of manufacturing sensors.

The Inventors appreciate that a conventional foldable sensor is prone to breaking. As a feature of a foldable sensor, the substrate upon which the conductive material is printed on folds over and therefore creases to connect the two components of a sensor. This arrangement of folding and connecting the sensor elements to form a sensor causes the conductive material to crease and stresses the conductive material. Such stress can break the connection and render the sensor inoperable and/or unreliable.

Additionally, the Inventors appreciate that the flexibility of a sensor can be impacted by its interface with the sensing circuit. In this respect, as is well known, the sensor is coupled to an electronic circuit that provides processing, power, and other functionality however, the wires or other physical material that connect the sensor to the circuit board can impact the overall flexibility and usability of the sensor.

Accordingly, the Inventors have recognized that there does not need to be a compromise between manufacturability and reliability of a sensor. The Inventors have conceived of a sensor construction where the sensor does not require the conductive material to have a continuous structural connection to operate (such as a physical continuous conductive trace of a single conductive material). Doing so allows the sensor to be more compact and reliable than other foldable sensors.

Accordingly, the Inventors have conceived of an arrangement that overcomes these shortcomings by the application of an anisotropic adhesive to a foldable sensor.

The Inventors have recognized that a foldable sensor that includes a substrate, a conductive trace, a sensor material, and an anisotropic adhesive can make a more reliable sensor. According to one embodiment, the conductive trace is disposed onto a continuous substrate that is configured to fold onto itself. This fold differentiates the substrate into a first substrate and a second substrate. The conductive trace includes at least a first plate portion disposed on the first substrate and a second plate portion disposed on the second substrate. It should be appreciated that the plate portions may sometimes be referred as a button(s). When the substrate is in its folded state, the first plate portion aligns with the second plate portion. Continuing from the first plate portion is a first conductive lead, and continuing from the second plate portion is a second conductive lead. The first and the second conductive leads mutually terminate at an interface that is on either the first substrate or the second substrate. Such interface may be used for connection to a suitable electronic circuit. Additionally, a sensor material is disposed onto at least one of the plate portions. The sensor material on one of the plate portions will align with plate portion on the opposing substrate.

The sensor additionally includes an anisotropic adhesive. An anisotropic adhesive is selectively conductive, so that current can only travel across the adhesive in one direction. In this configuration, the anisotropic adhesive will transfer current in the z-direction (i.e. the direction perpendicular to both of the planes of the first and second substrate when the sensor is in the folded configuration) but not in the x- or y-direction. Accordingly, even though the anisotropic adhesive may cover both of the conductive leads, they will remain electrically insulated from each other so long as they do not cross in the z-direction.

As mentioned above, in order to reach the interface, at least one of the conductive leads needs to terminate on the opposite side of the fold from where it originated. Accordingly, this conductive trace that is on both the first and the second substrate, can cross itself on different planes (i.e. on different substrates-that is, from the first substrate to the second substrate) in the z-direction. Because of this intersection, the anisotropic adhesive can conduct the current from the conductive trace across the substrates, Therefore, even if the conductive trace broke at the fold, or was otherwise not structurally continuous with itself (hereinafter called “structurally continuous”), then it could still conduct a current (hereinafter “functionally continuous”) through the anisotropic adhesive. Accordingly, the conductive trace is functionally continuous when it functionally aligns with itself in the z-direction and is connected to itself with the anisotropic adhesive.

In the depicted embodiment, the adhesive creates a continuous perimeter around the sensor material and conductive trace assembly. This perimeter is known as a boundary. This boundary does not need to be continuous or equidistant, and, as discussed below, the adhesive may be disposed onto the substrate in many different configurations. However, the plate portion on the first substrate should not be functionally connected to the plate portion on the second substrate with the anisotropic adhesive. In this regard, application of the adhesive material is masked from the plate portions and sensor material.

In some embodiments, the anisotropic adhesive covers the entirety of the second substrate excluding the plate portion/sensor material. However, this disclosure is not intended to be limiting. The anisotropic adhesive may be limited to only cover the interface and portions of the first conductive lead, so that communication between the first and second substrate is enabled even without a continuous structural connection. In this embodiment, another adhesive may supplement the support provided by the anisotropic adhesive, and alone may be sufficient to keep the sensor folded.

Alternatively, the anisotropic adhesive may be so expansive as to cover both the second substrate and the first substrate excluding the first and second plate portions. Accordingly, it should be understood that the anisotropic adhesive may cover the foldable sensor in some combination of the above (i.e. where the anisotropic adhesive is placed on the intersect of the first conductive lead on the first substrate and the first conductive lead on the second substrate and a portion of the interface; where the anisotropic adhesive is placed on the first substrate excluding the plate portion and on the interface portion of the second substrate; or covering the first and second conductive leads and the interface on the second substrate but not the entirety of the foldable substrate, etc.)

In the depicted embodiment, the anisotropic adhesive also acts to secure the foldable sensor in the folded state. This may be accomplished even when the anisotropic adhesive is disposed on only a portion of the foldable sensor. Furthermore, in some configurations, portions of the adhesive may not be anisotropic adhesive, as other adhesives or other means of securing the first and the second substrate may be implemented. In some embodiments, it may be desirable to use an electrically insulating adhesive with the anisotropic adhesive to isolate some of electrical components at selected locations. Of course, a single application of conductive anisotropic adhesive achieves both functions of holding the sensor together and allowing for functionally continuous current flow.

In the depicted embodiment the conductive trace is formed by printing a conductive silver paste onto the flexible substrate. However, this disclosure is not limiting, as other conductive materials, or combination of conductive materials, may be substituted into the conductive paste, such as but not limited to gold, copper, platinum, lead, tin, nickel, chrome and the like.

In some embodiments, the conductive trace may be printed onto the substrate. In other embodiments, the conductive trace is etched onto the flexible substrate. Furthermore, other means of disposing the conductive trace on to the substrate may be substituted.

The pattern of the conductive leads may be impacted by the placement of the anisotropic adhesive. As stated above, the first conductive lead does not need to be structurally continuous across the two substrates, instead, it needs to be functionally continuous. Accordingly, if the first conductive trace on the first substrate crosses the second conductive trace on the second substrate at a point where the anisotropic adhesive is covering the first or second substrate, then the sensor will short circuit. However, if the first conductive trace crosses the second conductive trace at a point where there is no anisotropic adhesive, then the circuit may still function provided there is suitable electrical insulation between the two. Furthermore, in some circumstances, it may be beneficial for the functionality of the sensor to have portions of the first conductive trace intersect with portions of the second conductive trace in the z-direction without anisotropic adhesive (such as for example, at the cooperating surfaces of the sensor material).

In the detailed embodiments, the conductive trace is disposed on the substrate with a mostly consistent pattern. After the first conductive lead curves around the second plate portion on the second substrate, the two conductive leads are linear and parallel to each other. However, this is not intended to be limiting, as the conductive traces can be placed in any pattern that will not short the sensor and that end at the interface. In some embodiments, the sensor may have an “L” configuration, or an “S” configuration. Furthermore, the interface may extend a distance that is not proportional to the sensors depicted in the figures.

The depicted embodiments the plate portion of the sensor includes two layers of sensor material, positioned between two layers of the conductive trace. However, this disclosure is not intended to be limiting, as there may be a single layer of sensor material disposed on one plate portion and positioned between both plate portions. Furthermore, in other embodiments, there may be another integer of sensor material.

In the depicted embodiment, the sensor material is larger than the plate portion of the conductive trace. However, in an alternative embodiment, the sensor material may be the same size as or smaller than the plate portion of the conductive trace.

In some embodiments, the sensor material is made of piezoelectric material. This material may be a natural piezoelectric material, such as quartz, or it may be a synthetic material, such as a ferroelectric ceramic. Furthermore, the piezoelectric sensor material may be formulated from one or a combination of the accepted categories of piezoelectric material, such as crystalline material, piezoceramics, piezoelectric semiconductor, polymer, piezoelectric composites, or glass ceramics. However, other materials with similar properties that may be reasonably implemented, but that do not align within said categories, may also be substituted.

In some embodiments, the sensor detects pressure through the electrical changes of the piezoelectric material. In this configuration, when the two plate portions of the sensor are pressed together, the force results in a change in the piezoelectric material's charge, which can be converted to a force based on the known properties of the material by an external processor. This processor is connected to the sensor device at the interface.

In some embodiments, the sensor may not be used to detect pressure, rather it is used to detect acceleration. In this embodiment, another structure with a known mass, not detailed in the figures, may be used to apply the force to the piezoelectric material to detect acceleration. However, in other embodiments, the sensor may detect other changes such as, but not limited to changes in temperature, vibration, strain, or force.

In some embodiments, the sensor includes a substrate that is formed from a single continuous material. In this configuration the substrate includes a first substrate and a second substrate. In the first unfolded state, the conductive trace and the sensor material are disposed in an unbroken pattern across the top of both the first substrate and the second substrate. The first and second substrate are defined by a folding line. The folding line delineates where the sensor should fold so that the sensor elements (i.e. the plate portion and the sensor material) on the first substrate functionally align with the sensor elements on the second substrate. It should be noted that the sensor elements are functionally aligned when the first plate portion is fully aligned or partially aligned with the second plate portion. When the sensor elements are functionally aligned, they in an arrangement where the sensor can detect the desired stimulus. Accordingly, the folding line ensures that when the sensor is in the folded state, the sensor elements are functionally aligned. In some embodiments this line is cut onto the substrate before the conductive trace is disposed on the substrate. However, in other embodiments the folding line may be cut after the conductive trace is disposed on the substrate. Alternatively, it may be cut after the anisotropic adhesive is disposed on the substrate.

In some embodiments, the folding line may alternatively be a perforated line. Furthermore, another structure as appreciated by this disclosure may be substituted. Alternatively, in some embodiments, the folding line is not a physical structure, and instead is an imaginary line across the substrate.

In the depicted embodiments, the folding line is perpendicular to the interface. However, in alternative embodiments, without changing the location of the interface, the folding line may be parallel or oblique to the interface. Accordingly, the folding line can impact the direction of the conductive trace. Moreover, the interface is not required to be at the bottom edge of the sensor as depicted in the figures, as this explanation is not intended to be limiting. Therefore, the location of the interface with the direction of the folding line may impact the pattern of the conductive trace.

In some embodiments, the foldable sensor includes a substrate that is formed of a flexible non-conductive material. In some embodiments, the substrate is composed of Biaxially-oriented polyethylene terephthalate ((brand name Mylar, trademark product of DuPont Corp. of Wilmington, Del.) or another polyethylene terephthalate (PET) material. However, other electrically insulating materials that are flexible enough to permit the two plate portions to align, may be substituted. Furthermore, in some embodiments, the substrate only needs to be electrically insulating.

In other embodiments, where the first and the second substrate are separated from each other, the substrate may not be flexible and instead, it may be formed from two rigid electrically insulating structures. In this configuration, when the sensor is in the first unfolded (or rather the separated) state, the conductive traces and sensor materials are disposed onto the top surface of each substrate. Accordingly, when the substrate is in the second folded (or rather the functionally aligned) state, like in other embodiments, the first and second plate portions are functionally aligned so that they are electrically connected through the sensor material. As mentioned above, when the sensor elements are functionally aligned, the sensor elements are aligned in an arrangement where the sensor can detect the desired stimulus. Accordingly, when the sensor elements are functionally aligned, the sensor is in a functionally aligned state. Furthermore, the first conductive lead on the first substrate aligns with at least one portion of the first conductive lead on the second substrate where there is the anisotropic adhesive. The first conductive lead is functionally aligned when the first conductive lead on the first substrate intersects with the first conductive lead on the second substrate, and when this intersection can transfer the signal from the first conductive lead on the first substrate to the first conductive lead on the second substrate. However, in this configuration the substrate may not be rigid, rather it is just not flexible enough to fold over onto itself.

In some embodiments, when the sensor is in the first configuration, the first substrate is connected to the second substrate, but when the sensor is positioned into its folded configuration, the first substrate is no longer connected to the second substrate. In this configuration, the boundary line between the first and the second substrate breaks, and the substrates are severed. Accordingly, the first conductive trace is also no longer structurally connected across the boundary line. However, the sensor is still functionally connected through the anisotropic adhesive.

In the depicted embodiment, the interface is on a portion of the second substrate that is defined by an overhang. In this configuration, the first and second substrate are equal in width (x-direction) but have different lengths (y-direction). Therefore, there is a portion of the second substrate that is not covered by the first substrate, which is defined as an overhang. The first and second conductive leads terminate at this overhang, and at least part of this region is covered in anisotropic adhesive. This mutual termination and conductivity enables the interface to communicate with an set of exposed pads on a circuit board

In some embodiments, the first and the second substrate may be the same length and the width. In this configuration, the first and the second substrate may not be continuous, so that when the sensor is folded, both the first substrate and the second substrate have an overhang. However, the sensor elements will still align, and the interface is defined by the termination point of both of the conductive leads.

In other configurations, where the first and the second substrate are the same length and the width, the first substrate may not be a rectangle or be identical to the second substrate. Instead, the first substrate may have a portion cut out, so that the interface can be secured to the circuit.

In the depicted embodiment, the sensor is connected to an external circuit board (or alternate processing device) at an interface with an anisotropic adhesive. In this configuration, the anisotropic adhesive on the interface functionally connects the sensor to the exposed electrical pads on the circuit board. However, other means of connecting the sensor to a circuit board or to another device, such as traditional wires that pierce the conductive leads and the substrate may be substituted.

The anisotropic adhesive may be any adhesive that is electrically conductive in the z-direction. Accordingly, this adhesive may be an epoxy-type adhesive, an urethane-type adhesive, an acrylate-type adhesive, a silicone-type adhesive or a blend of adhesives. However, this disclosure is not limiting. In some embodiments, the anisotropic adhesive is an epoxy/acrylate-blend adhesive system filled with 43-micron silver-coated glass beads (such as Anisotropic Conductive Film 7303 by 3M™). However, other anisotropic adhesives may be substituted.

In the depicted embodiment, the plate portion and the sensor material are disposed into the substrate in a circle. However, this disclosure is not limiting, and the plate portion and the sensor material may be disposed on the substrate in different geometries.

In some embodiments, the plate portion and the sensor material are both around 1 mm wide. However, the plate portion and the sensor material may be than or equal to 1 mm, 2 mm, 5 mm or 10 mm.

In some embodiments, the substrate may be cut by the user. A user may receive a sheet of sensors, where they select the amount and length of the sensor components and cut the substrate to the desired size. Alternatively, in other embodiments, the substrate is not easy to cut, and the final dimension of the sensor is predetermined. In other embodiments, the sensor may be fabricated so that a single sensor is on a piece of the substrate.

Turning to the figures, specific non-limiting embodiments are described in further detail. It should be understood that the various systems, components, features, and methods described relative to these embodiments may be used either individually and/or in any desired combination as the disclosure is not limited to only the specific embodiments described herein.

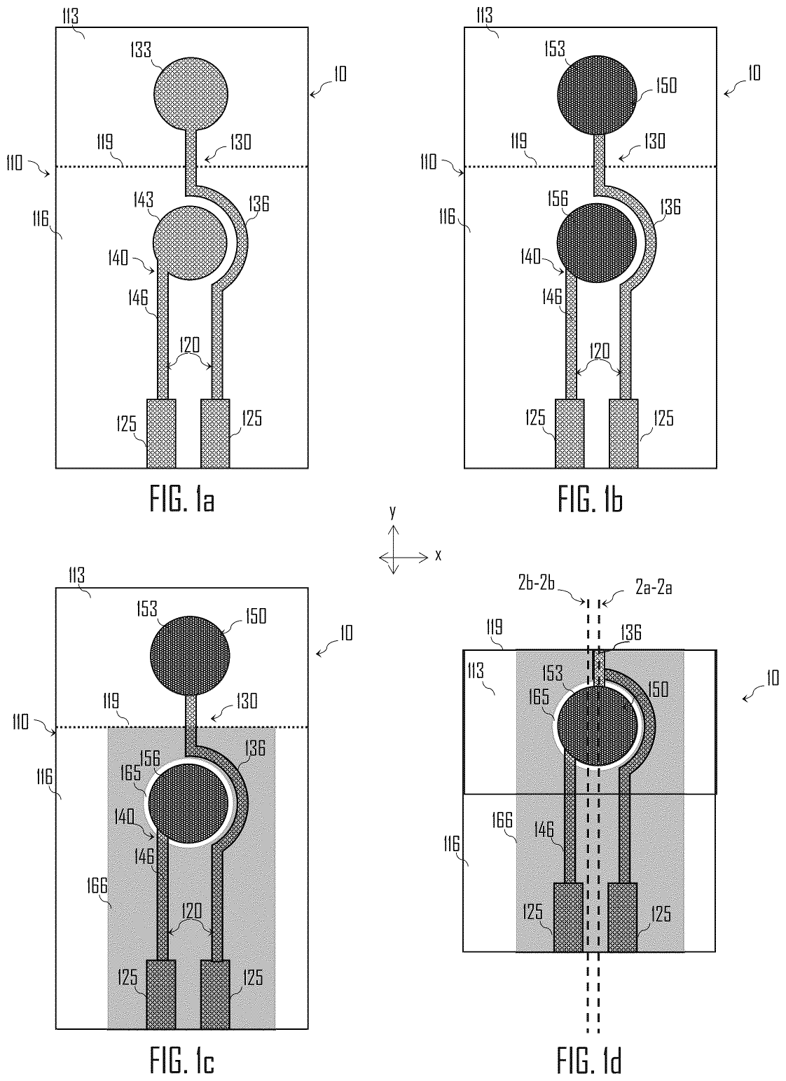

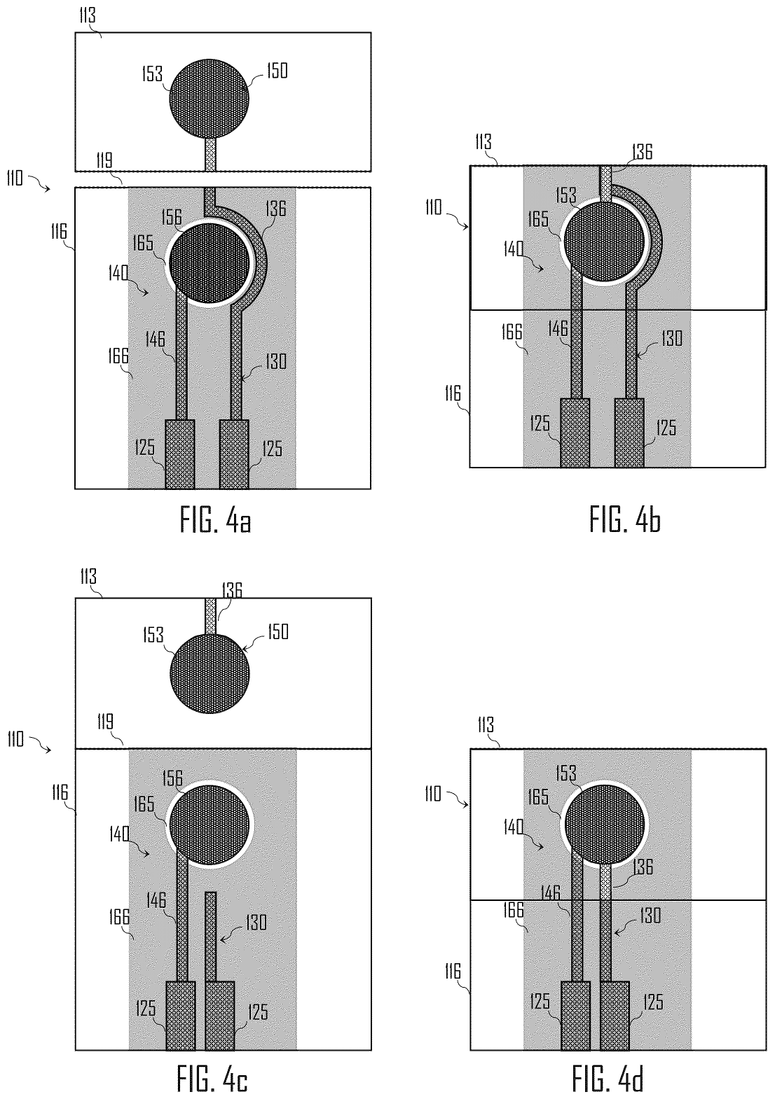

FIGS. 1a-1d illustrate various stages of the construction of the sensor 10. FIG. 1a depicts a conductive trace 120 disposed onto a flexible substrate 110. As detailed above, the flexible substrate 110 includes two portions, a first substrate 113 and a second substrate 116. In depicted embodiment, the first substrate and the second substrate are unequally divided by a folding line 119. In this embodiment, the folding line is a perforated line and the first and second substrate are formed from a continuous material. As noted above and illustrated and discussed in FIG. 4a-b, the first and second substrate may be separated (and/or detached) from each other in their unfolded state (e.g. a first state), and are connected and/or mated to each other as they transition into their folded state (e.g. a second state) where they are functionally aligned.

The flexible substrate 110 supports the sensor unit, as the conductive traces, among other elements, are disposed onto the substrate 110. Therefore, when the sensor is in the first unfolded position, the substrate holds the sensor elements in a stable (isolated) position relative to each other. The substrate may be comprised of an electrically insulating material, as to it enable other electrical elements, such as the conductive trace, to properly conduct electric signals when the sensor is functionally aligned. As illustrated in FIG. 1a, the conductive trace 120 is disposed on both the first substrate and the second substrate.

The conductive trace 120 that is on the first substrate 113 is the first conductive trace 130. The first conductive trace 130 includes two sub-elements, a first plate portion 133 and a first conductive lead 136. The first conductive lead 136 stems from the first plate portion 133 on the first substrate 113 and ends at an interface 125 on the second substrate 116. In the depicted embodiment, the first conductive lead 136 travels from the first plate portion, across the folding line 119 and ends on the second substrate 116. However, as detailed further below, the first conductive lead 136 can cross the first substrate 113 and the second substrate 116 without crossing the folding line 119. Accordingly, this disclosure is not limiting, and other structures that permit the first conductive trace to cross from the first substrate to the second substrate may be substituted. Furthermore, as previously discussed, operation of the sensor is not dependent upon the structural continuity of the first connective lead. However, it is depicted to be continuous in FIG. 1 as the conductive lead is disposed onto the substrate over the folding line.

The second conductive trace 140 similarly includes a second plate portion 143 and a second conductive lead 146. The second plate portion 143 is disposed on the second substrate 116. The second conductive lead 146 stems from the second plate portion 143 and terminates at the interface 125 on the second substrate.

When the sensor 10 is in its unfolded state, the conductive traces 120 are all positioned on the same side, the top of the first substrate and the top of the second substrate. Accordingly, the first conductive trace 130 will not intersect with the second conductive trace 140 unless, it is disposed into the substrate 110 in that pattern. However, when the sensor is in the second folded state, because the top of the first substrate 113 aligns with the top of the second substrate 116, there is a risk that the first conductive lead 136 may intersect with the second conductive lead 146, which may be undesirable. Conversely, the first plate portion 133 should align with the second plate portion 143, and the first conductive lead 136 on the first substrate 113 should align with the first conductive lead 136 on the second substrate 116. Accordingly, as depicted in FIGS. 1a & 1d, the first plate portion 133 is disposed on the first substrate 113 to align with the second plate portion 143 on the second substrate 116 when the sensor is folded. Additionally, when the sensor is in a folded state, at least one portion of the first conductive lead 136 is disposed on the first substrate 113 to align with another portion of the first conductive lead 136 on the second substrate 116. Furthermore, the first conductive lead 136 on the first substrate 113 and the second substrate 115 may be disposed as to not align with any portion of the second conductive lead 146.

As illustrated in FIG. 1b, the first conductive lead 136 and the second conductive lead 146 terminate on the same side of the second substrate 116. As discussed above, this location is the interface 125. In addition to the mutual termination of the conductive leads on the second substrate, when the sensor is folded, the second substrate 116 at the interface 125 is not covered by the first substrate 113.

FIG. 1b depicts the conductive trace and flexible substrate of FIG. 1a, with the addition of a sensor material 150. In the depicted embodiment, the sensor material includes a first sensor material 153 and a second sensor material 156. However, in other embodiments there may only be a first or a second sensor material. The first sensor material 153 is disposed onto the first plate portion 133; while the second sensor material 156 is disposed on the second plate portion 143. In the depicted embodiment, the sensor material 150 extends beyond the outer bounds of the first plate portion 133 and second plate portion 143. However, in other embodiments the sensor material may be sized to match or fit within the geometry of its associated plate portions.

FIG. 1c depicts the foldable sensor in an unfolded state. As stated above, the foldable sensor includes the conductive trace 120, the flexible substrate 110, the sensor material 150, and an anisotropic adhesive 166. In this unfolded state, the first substrate 113 and second substrate 116 may be spaced from each other in a disconnected configuration, as the sensor circuit is incomplete because the first and second conductive traces are electrically disconnected.

The anisotropic adhesive 166 is disposed on the flexible substrate 110 and parts of the conductive leads. In the depicted embodiment, the anisotropic adhesive 166 is shown to cover the majority of the second substrate 116-excluding the second plate portion 143. In this configuration, the anisotropic adhesive 166 is spaced from the sensor material. Accordingly, there is a boundary 165 around the second sensor material 156 where there is no anisotropic adhesive. This boundary 165 ensures that the first plate portion 133 is functionally connected to the second plate portion 143 through the sensor material 150 and not by the anisotropic adhesive 166.

As detailed above, the anisotropic adhesive 166 may cover the entirety of the second substrate 116 excluding the second plate portion 143 and the second sensor material 156. However, it may cover the entirety of the foldable substrate 110, excluding the plate portions 143, 133 and the sensor material 150. Alternatively, the anisotropic adhesive may cover portions of the second substrate, like the interface 125 and the intersect of the first conductive lead 136 on the first substrate 113 and the second substrate 116. Alternatively, the anisotropic adhesive may cover portions of the first substrate and the second substrate, i.e. covering the interface on the second substrate and the intersect of the first conductive lead 136 between the two substrates on the first substrate. However, other configurations may be substituted.

Accordingly, to manufacture the sensor according to the depicted embodiment, one would follow the arrangement illustrated in FIGS. 1a-c. A substrate is divided by a perforated cut over the folding line 119. The conductive trace 120 is disposed onto the substrate 110. This is includes disposing a first conductive trace 130 onto the first substrate 113 and the second substrate 116. The first plate portion 133 is disposed on the first substrate 113; while the first conductive lead 136 is disposed on the first substrate 113 and the second substrate 116 from the first plate portion 133 to the interface 125. Additionally, the second conductive trace 140, including the second plate portion 143 and the second conductive lead 146, is disposed onto the second substrate 116. The second conductive lead 146 starts at the second plate portion 143 and ends at the interface 125. The sensor material 150 is disposed on the first plate portion 133 and the second plate portion 143. The anisotropic adhesive 166 is disposed on the second substrate 116 to functionally connect the first conductive lead 136 on the first substrate 113 to the first conductive lead 136 on the second substrate 116. The anisotropic adhesive additionally functionally connects the second conductive lead 146 and the first conductive lead 136 on the interface 125 to a printed circuit board or alternate unclaimed structure.

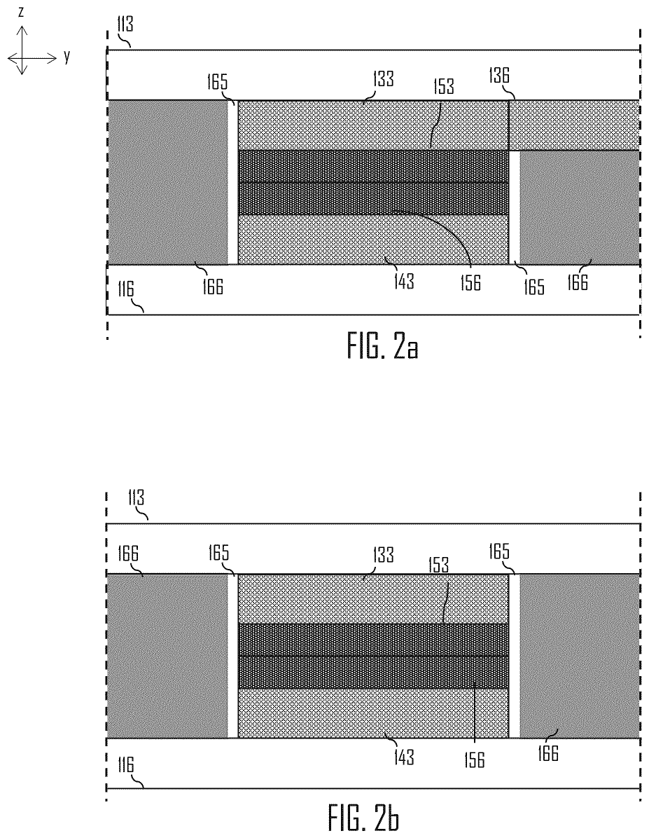

FIG. 1d depicts the foldable sensor in the folded state. In this state, the top of the first substrate 113 is connected to the top of the second substrate 116. In the depicted embodiment, the anisotropic adhesive 166 holds the sensor in the folded state. Furthermore, this adhesive may ensure that the first plate portion 133 and the second plate portion 143 are aligned, and the first sensor material 153 contacts the second sensor material 156. (see FIGS. 2a-b for more detail). However, as stated above, the anisotropic adhesive does not directly contact the first plate portion 133, the second plate portion 143, the first sensor material 153, or the second sensor material 156. Instead, there is a boundary 165 that surrounds those structures. In some cross sections, as depicted in FIG. 2a, there may be the substrate 110 outside of the boundary 165, and one of the conductive leads 136 within the boundary 165. At this cross section, the anisotropic adhesive 166 may connect the second substrate 116 to the first conductive lead 136 in the z-direction. In some alternative configurations, the first conductive lead 136 may be connected to the first substrate 113 on one side of the plate portion, and to the second substrate 116 on the other side of the plate portion. Although, in FIG. 2a, the first conductive lead 136 is depicted as the conductive lead within the boundary 165, the second conductive lead 146 will also cross the boundary at a different cross section. Furthermore, in other cross sections of the same embodiment, as illustrated in FIG. 2b, there may only be the substrate 110 surrounding the boundary 165 and no conductive leads. In this case, the anisotropic adhesive may extend from the first substrate 113 to the second substrate 116. However, in cross sections of other embodiments, the boundary may be surrounded by the substrate 110, and contain the first conductive trace 130 and the second conductive trace 140 on either side of the sensor material 150 and plate portions 133, 143. In this embodiment, if the anisotropic adhesive would functionally connect the leads outside of the boundary, then the first conductive lead 136 would not align with the second conductive lead 146 in the z-direction.

As stated above, in some embodiments, the anisotropic adhesive 166 may not be the only adhesive within the sensor. An alternative adhesive may be used to secure the first substrate 113 to the second substrate 116. This additional adhesive may be electrically insulating, so that the adhesive may contact the first plate portion 133, the second plate portion 143, the first sensor material 153, and/or the second sensor material 156. Furthermore, if there were portions of the first conductive lead 136 on the first substrate 113 that intersect with the second conductive lead 146 when the sensor is folded, the electrically insulating glue may be used to prevent functional attachment while still securing the sensor in its folded state.

FIGS. 1c & 1d illustrate how the anisotropic adhesive 166 may be disposed on the first conductive lead 136, the second conductive lead 146, and the second substrate 116. Once the foldable sensor is folded, the anisotropic adhesive 166 electrically connects at least a portion of the first conductive lead 136 between the first substrate 113 and the second substrate 116. The direction specific conductivity of the anisotropic adhesive 166 ensures that even though the adhesive covers both conductive leads, the current traveling through the first conductive lead 136 is isolated from the second conductive lead 146. Furthermore, because the conductivity is in the z-direction, electrical conductivity is not dependent on the structural connection of the first conductive lead 136 between the first substrate 113 and the second substrate 116. For the circuit to be completed, only a portion of the first conductive lead 136 on the first substrate 113 needs to overlap with the first conductive lead 136 on the second substrate 116 in the z-direction. In the depicted embodiment, even if the first conductive lead 136 is severed at the folding line 119, the sensor can still function. Accordingly, durability and reliability of the foldable sensor is not compromised by a decrease in structural support.

In the configuration detailed in FIG. 1d, and where the sensor material is a piezoelectric material, the device can sense a change in pressure. When a force is exerted in a z-direction on the plate portions, the piezoelectric material will deform and exhibit a change in electrical properties (such as change in capacity, current, voltage etc.). This signal is then carried throughout the sensor to the interface through the conductive leads and the anisotropic adhesive. The signal then is transmitted through the anisotropic adhesive to an external device at the interface. At the external device the known properties of the piezoelectric material will be used to calculate the change in pressure.

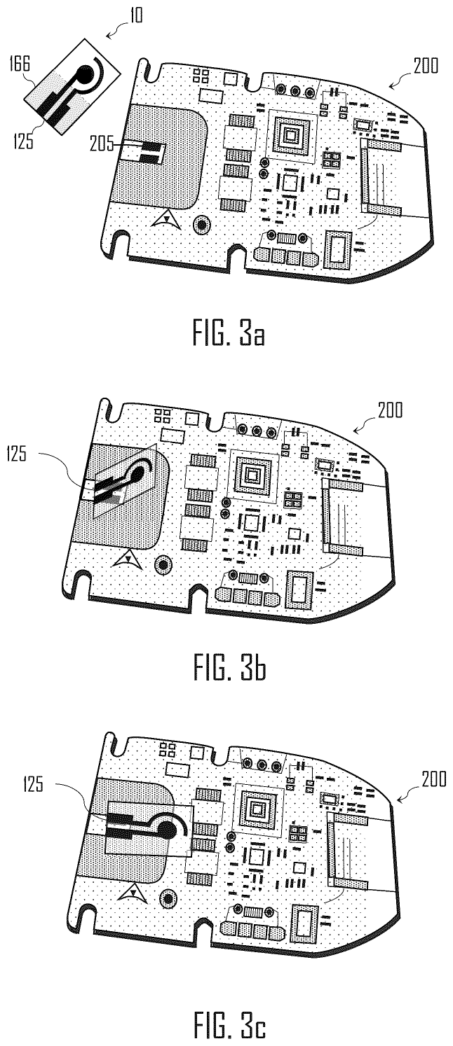

The anisotropic adhesive 166 can also form an electrical connection at the interface 125 between the sensor and an external device, such as a printable circuit board 200. The anisotropic adhesive at this location can act to create a more secure bond/electrical connection between the sensor and the circuit to which it attaches. FIGS. 3a-c depict the process of attaching the sensor to a printable circuit board 200 using the anisotropic adhesive 166. In FIG. 3a, the foldable sensor is folded, like in FIG. 1d, and the overhang between the first substrate 113 and the second substrate 116 exposes the anisotropic adhesive 166 coating the interface 125. As shown in FIG. 3b, the two conductive leads at the interface 125 are aligned with a pair of exposed pads 205 on the printable circuit board 200. Finally, in FIG. 3c the sensor is placed on the printed circuit board 200. The sensor is securely connected to the printed circuit board 200 through the interface 125 with the anisotropic adhesive. The anisotropic adhesive 166 that structurally connects the foldable sensor to the exposed pad 205, also carries the electric signal from the sensor to the circuit board 200.

FIGS. 4a-d depict some alternative embodiments.

As noted above, the sensor can be functionally aligned even when the first substrate portion and second substrate portion are not formed from a continuous substrate. In some instances, the first substrate and the second substrate may not be initially structurally connected. For example, in FIG. 4a, the second substrate 116 is detached from the first substrate 113. In this embodiment, the distance between the first plate portion 133 and a first side wall is identical to the distance between the second plate portion 143 and a second side wall. This identical distance creates a guide so when the side walls are aligned, the plate portions are aligned. It should be noted that because the first substrate 113 and second substrate 116 are not structurally continuous, the first conductive trace 130 is also not structurally continuous. However, as should be appreciated by the above disclosure, the first conductive trace 130 may be functionally connected to itself with the anisotropic adhesive 166. Moreover, there may be structural elements that may prompt this connection, such as the distance between a portion of the first conductive lead 136 and a side wall on the substrate 110 being identical on the first substrate 113 and the second substrate 116. This may serve as a guide so that the first conductive lead 136 on the first substrate 113 is electrically connected to the first conductive lead 136 on the second substrate 116 with the anisotropic adhesive 166, as illustrated in FIG. 4b. However, in this is not intended to be limiting, as other means of ensuring functional alignment of the sensor components may be substituted. Accordingly, in this embodiment, even though the sensor is not initially structurally continuous, functional alignment of the sensor renders it functionally continuous.

FIG. 4c depicts an alternative configuration for the conductive lead. In this embodiment, when the device is unfolded, the first conductive lead 136 on the first substrate 113 that extends away from the first conductive lead 136 on the second substrate 116. However, when the sensor is folded, the first conductive lead 136 on the first substrate 113 overlaps with the first conductive lead 136 on the second substrate 116. At this intersection, the first conductive lead 136 on the second substrate 116 is covered by an anisotropic adhesive 166. The anisotropic adhesive 166 enables the first conductive lead 136 on the first substrate 113 to functionally connect to the first conductive lead 136 on the second substrate 116. (see FIG. 4d).

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art. Accordingly, the foregoing description and drawings are by way of example only.

What is claimed is:

1. A sensor comprising:
a substrate divided into a first substrate portion and a second substrate portion;
a conductive trace disposed on the first substrate portion and the second substrate portion;
a sensor material disposed on the conductive trace; and
an anisotropic adhesive disposed on the conductive trace;
wherein the sensor is configured to transition from a first state where the first substrate portion is disconnected from the second substrate portion, and a second state where the first substrate portion overlies the second substrate portion.

2. The sensor of claim 1, wherein the first substrate portion and the second substrate portion are separated by a folding line, wherein the sensor is functionally aligned when the sensor is in the second state.

3. The sensor of claim 1, further including:
a first conductive trace with a first plate portion on the first substrate portion and a first conductive lead that terminates at an interface on the second substrate portion; and
a second conductive trace with a second plate portion on the second substrate portion and a second conductive lead originating at the second plate portion and terminating at the interface.

4. The sensor of claim 3, wherein the first conductive trace originates at the first plate portion on the first substrate portion and is functionally connected to the first conductive trace disposed on the second substrate portion with the anisotropic adhesive when the sensor is in the second state.

5. The sensor of claim 3, wherein the sensor material is disposed on at least one of the first plate portion and/or the second plate portion.

6. The sensor of claim 5, wherein when the sensor is functionally aligned, the sensor material is positioned between the first plate portion and the second plate portion.

7. The sensor of claim 3, wherein when the sensor is in the second state, the anisotropic adhesive contacts the first conductive lead and the second conductive lead and wherein the first conductive lead is isolated from the second conductive lead.

8. The sensor of claim 7, wherein the anisotropic adhesive is spaced from the first plate portion and the second plate portion.

9. The sensor of claim 1, further comprising an interface formed from the conductive trace and wherein the interface is configured to be functionally connected to a processor.

10. The sensor of claim 9, wherein the processor is a printed circuit board.

11. The sensor of claim 10, wherein the anisotropic adhesive is disposed on the interface, and is configured to electrically connect the sensor to a pair of exposed contact pads of the printed circuit board.

12. The sensor of claim 1, wherein the substrate is biaxially-oriented polyethylene terephthalate.

13. The sensor of claim 1, wherein the first substrate portion is connected to the second substrate portion with the anisotropic adhesive.

14. A sensor comprising;
a first substrate with a first substrate top;
a second substrate detached from the first substrate with a second substrate top that is configured to be mated to the first substrate top when the sensor is functionally aligned and including an overhang at least in part defined by a portion of the second substrate top that is spaced from the first substrate;
a conductive trace disposed on the first substrate top and the second substrate top;
a sensor material disposed on the conductive trace and positioned between the first substrate and the second substrate when the sensor is functionally aligned; and
an interface on the overhang wherein the conductive trace terminates at the interface.

15. The sensor of claim 14, further comprising:
a first conductive trace with a first plate portion disposed on the first substrate, and a first conductive lead connected to the first plate portion on the first substrate and connected to the interface on the second substrate,
wherein when the sensor is functionally aligned, the first conductive lead on the first substrate is not structurally continuous with the first conductive lead on the second substrate and the first conductive lead on the first substrate is functionally connected to the first conductive lead on the second substrate with an anisotropic adhesive.

16. The sensor of claim 15, further comprising:
a second conductive trace including a second plate portion on the second substrate, and a second conductive lead originating from the second plate portion and terminating at the interface,
wherein when the sensor is functionally aligned, the sensor material is positioned between the first plate portion and the second plate portion.

17. The sensor of claim 16, wherein the first substrate is directly mated to the second substrate with an adhesive.

18. The sensor of claim 17, wherein the adhesive is the anisotropic adhesive, and wherein the anisotropic adhesive is spaced from the first plate portion, the second plate portion and the sensor material.

19. The sensor of claim 14, wherein an anisotropic adhesive is disposed on the interface and is configured to electrically connect the sensor to a pair of exposed contact pads of a printed circuit board.

20. The sensor of claim 14, wherein the interface is configured to electrically connect the sensor to a processor.
